(19) United States
(12) Patent Application Publication
(10) Pub. No.: US 2012/0305933 A1
(43) Pub. Date: Dec. 6, 2012

(54) GROUP III NITRIDE SEMICONDUCTOR LIGHT-EMITTING DEVICE

(75) Inventors: Seiji NAKAHATA, Itami-shi (JP); Fumitake NAKANISHI, Itami-shi (JP)

(73) Assignee: SUMITOMO ELECTRIC INDUSTRIES, LTD., Osaka-shi (JP)

(21) Appl. No.: 13/417,830

(22) Filed: Mar. 12, 2012

Related U.S. Application Data
(60) Provisional application No. 61/492,030, filed on Jun. 1, 2011.

(30) Foreign Application Priority Data
Jun. 1, 2011 (JP) 2011-123242

(51) Int. Cl. H01L 33/32

(52) U.S. Cl. 257/76; 257/E33.025

(57) ABSTRACT

A group III nitride semiconductor light-emitting device includes a GaN crystal substrate and at least one group III nitride semiconductor layer disposed on a main surface of the GaN crystal substrate. The substrate includes a matrix crystal region and a c-axis-inverted crystal region. An off angle θ is formed between the main surface and a {0001} plane, and an off-angle component of a first direction has an absolute value |θ₁| of 0.03° or more and 1.1° or less and an off-angle component of a second direction has an absolute value |θ₂ of 0.75×|θ₁| or less, where the first direction is one of <10-10> and <1-210> directions and the second direction is the other thereof. Accordingly, the group III nitride semiconductor light-emitting device with excellent characteristics including the group III nitride semiconductor layer having good morphology and uniform physical properties and formed on the GaN crystal substrate is obtained.

### BACKGROUND OF THE INVENTION

1. Field of the Invention

The present invention relates to a group III nitride semiconductor light-emitting device having excellent characteristics, the device includes a GaN crystal substrate, and the substrate includes a matrix crystal region and a c-axis-inverted crystal region.

2. Description of the Background Art

The GaN crystal substrate is widely used as a substrate for a semiconductor light-emitting device such as LED (light-emitting diode) and LD (laser diode). In order to improve the characteristics of the semiconductor light-emitting device, a GaN crystal substrate having a low dislocation density is now under development.

A method for manufacturing a GaN crystal substrate having a low dislocation density is disclosed for example in Japanese Patent Laying-Open No. 2003-165799 (PTL 1) and Japanese Patent Laying-Open No. 2003-183100 (PTL 2) in which a facet growth method is proposed. Specifically, a GaN crystal is grown on a base substrate on which a mask layer is provided, facets are formed at predetermined positions in the process of growing the GaN crystal, and accordingly dislocations are caused to gather in a predetermined site. Dislocations represented by vectors of different signs are coupled together and thus the dislocations are reduced.

### SUMMARY OF THE INVENTION

According to the facet growth method proposed for example in Japanese Patent Laying-Open Nos. 2003-165799 (PTL 1) and 2003-183100 (PTL 2), a GaN crystal substrate having a low dislocation density can be obtained. If a group III nitride semiconductor layer is grown on such a GaN crystal substrate, however, a protrusion in the shape of a hexagonal pyramid may be formed or a depression in the shape of a crescent may be formed on the crystal growth surface of the group III nitride semiconductor layer. Thus, a problem arises that a group III nitride semiconductor layer having good morphology and uniform physical properties is difficult to grow and consequently a group III nitride semiconductor light-emitting device having excellent characteristics is difficult to fabricate.

An object of the present invention is to solve the problem above and provide a group III nitride semiconductor light-emitting device with excellent characteristics including a group III nitride semiconductor layer having good morphology and uniform physical properties and grown on a GaN crystal substrate.

The present invention according to an aspect is a group III nitride semiconductor light-emitting device including a GaN crystal substrate and at least one group III nitride semiconductor layer disposed on a main surface of the GaN crystal substrate, and the GaN crystal substrate includes a matrix crystal region and a c-axis-inverted crystal region. A <1-210> direction of a crystal in the c-axis-inverted crystal region is oriented identically to a <1-210> direction of a crystal in the matrix crystal region, and a <0001> direction of the crystal in the c-axis-inverted crystal region is inverted relative to a <0001> direction of the crystal in the matrix crystal region. An off angle θ is formed between the main surface and a {0001} plane, and an off-angle component of a first direction has an absolute value |θ₁| of not less than 0.03° and not more than 1.1° and an off-angle component of a second direction has an absolute value |θ₂| of not more than 0.75×|θ₁|, where the first direction is one of <10-10> and <1-210> directions and the second direction is the other of them.

In the group III nitride semiconductor light-emitting device of the present invention, the group III nitride semiconductor layer may have a laser diode structure including a first-conductivity-type layer, an active layer, and a second-conductivity-type layer. The group III nitride semiconductor layer may also have a light-emitting diode structure including a first-conductivity-type layer, an active layer, and a second-conductivity-type layer.

The present invention can provide a group III nitride semiconductor light-emitting device with excellent characteristics including a group III nitride semiconductor layer having good morphology and uniform physical properties and grown on a GaN crystal substrate.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic plan view showing an example of a part of the group III nitride semiconductor light-emitting device according to the present invention.

FIG. 2 is a schematic cross section along II-II in FIG. 1.

FIG. 3 is a schematic cross section along III-III FIG. 1.

FIG. 4 is a schematic plan view showing an example of a part of a typical group III nitride semiconductor light-emitting device.

FIG. 5 is a schematic cross section along V-V in FIG. 4.

FIG. 6 is a schematic cross section showing an example of the group III nitride semiconductor light-emitting device according to the present invention.

FIG. 7 is a schematic cross section showing another example of the group III nitride semiconductor light-emitting device according to the present invention.

FIG. 8 is a schematic plan view showing an example of a GaN crystal substrate in the group III nitride semiconductor light-emitting device according to the present invention.

FIG. 9 is a schematic cross section along IX-IX in FIG. 8.

FIG. 10 is a schematic cross section along X-X in FIG. 8.

FIG. 11 is a flowchart showing a method for manufacturing a group III nitride semiconductor light-emitting device.

FIG. 12 is a schematic plan view showing a sub step of forming a mask on a base substrate in the step of preparing a GaN crystal substrate according to the method for manufacturing a group III nitride semiconductor light-emitting device in the present embodiment.

FIG. 13 is a schematic cross section showing a sub step of forming a GaN crystal substrate by growing and processing a GaN crystal on the base substrate on which the mask is formed, in the step of preparing a GaN crystal substrate according to the method for manufacturing a group III nitride semiconductor light-emitting device in the present embodiment.

FIG. 14 is a graph showing absolute value |θ₁| of an off-angle component of the <10-10> direction defined as a first direction and absolute value |θ₂| of an off-angle component of the <1-210> direction defined as a second direction, of a main surface of a GaN crystal substrate in each example of Example A of the group III nitride semiconductor light-emitting device according to the present invention.

FIG. 15 is a graph showing absolute value |θ₂| of an off-angle component of the <10-10> direction defined as a second direction and absolute value |θ₁| of an off-angle component of the <1-210> direction defined as a first direction, of a main surface of a GaN crystal substrate in each example of Example B of the group III nitride semiconductor light-emitting device according to the present invention.

FIG. 16 is a graph showing absolute value |θ₁| of an off-angle component of the <10-10> direction defined as a first direction and absolute value |θ₂| of an off-angle component of the <1-210> direction defined as a second direction, of a main surface of a GaN crystal substrate in each example of Example C of the group III nitride semiconductor light-emitting device according to the present invention.

FIG. 17 is a graph showing absolute value |θ₂| of an off-angle component of the <10-10> direction defined as a second direction and absolute value |θ₁ of an off-angle component of the <1-210> direction defined as a first direction, of a main surface of a GaN crystal substrate in each example of Example D of the group III nitride semiconductor light-emitting device according to the present invention.

### DESCRIPTION OF THE PREFERRED EMBODIMENTS

### Group III Nitride Semiconductor Light-Emitting Device

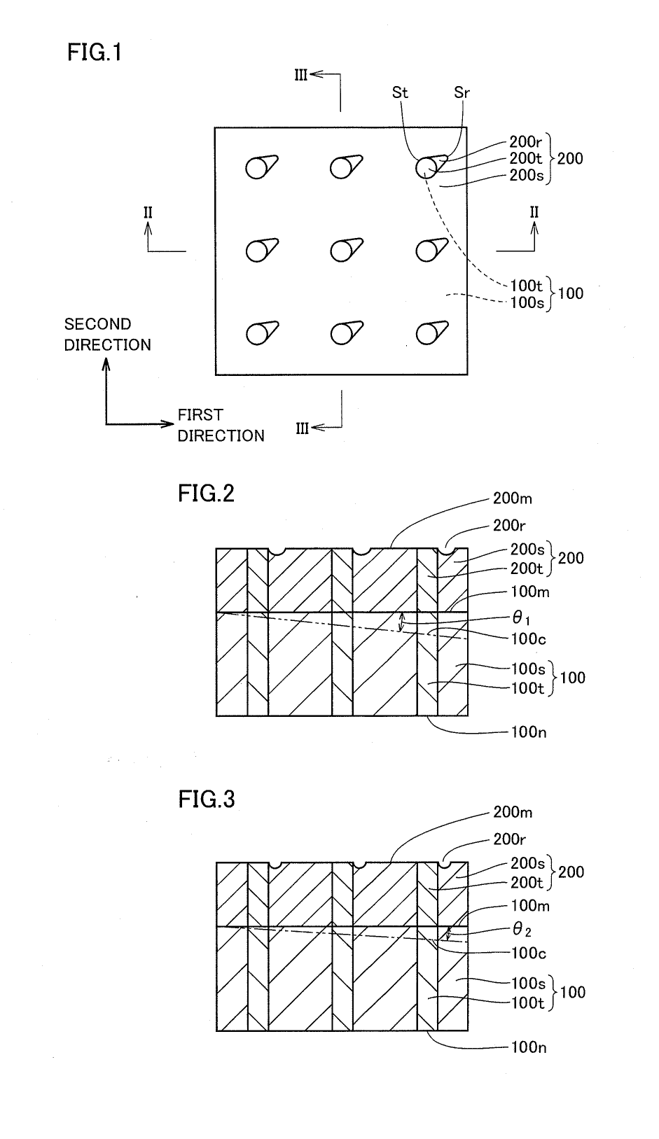

Referring to FIGS. 1 to 3, 6, and 7, a group III nitride semiconductor light-emitting device 10 in an embodiment of the present invention includes a GaN crystal substrate 100 and at least one group III nitride semiconductor layer 200 disposed on a main surface 100m of GaN crystal substrate 100. Here, GaN crystal substrate 100 includes a matrix crystal region 100s and a c-axis-inverted crystal region 100t. The <1-210> direction of the crystal in c-axis-inverted crystal region 100t is oriented identically to the <1-210> direction of the crystal in matrix crystal region 100s, while the <0001> direction of the crystal in c-axis-inverted crystal region 100t is inverted relative to the <0001> direction of the crystal in matrix crystal region 100s. An off angle is formed between main surface 100m and a {0001} plane, and an off-angle component of a first direction has an absolute value |θ₁| of not less than 0.03° and not more than 1.1° and an off-angle component of a second direction has an absolute value |θ₂| of not more than 0.75×|θ₁|, where the first direction is one of the <10-10> direction and the <1-210> direction and the second direction is the other thereof. Here, c-axis-inverted crystal region 100t may or may not be included in group III nitride semiconductor light-emitting device 10.

Group III nitride semiconductor light-emitting device 10 in the present embodiment has GaN crystal substrate 100 which includes matrix crystal region 100s and c-axis-inverted crystal region 100t. Regarding off angle θ between main surface 100m and the {0001} plane, absolute value |θ₁| of the off-angle component of the first direction is not less than 0.03° and not more than 1.1° and absolute value |θ₂| of the off-angle component of the second direction is not more than 0.75×|θ₁|, where the first direction is one of the <10-10> direction and the <1-210> direction and the second direction is the other thereof. Accordingly, on GaN crystal substrate 100, group III nitride semiconductor layer 200 having good morphology and uniform physical properties is grown, and thus group III nitride semiconductor light-emitting device 10 having excellent characteristics is formed.

GaN Crystal Substrate

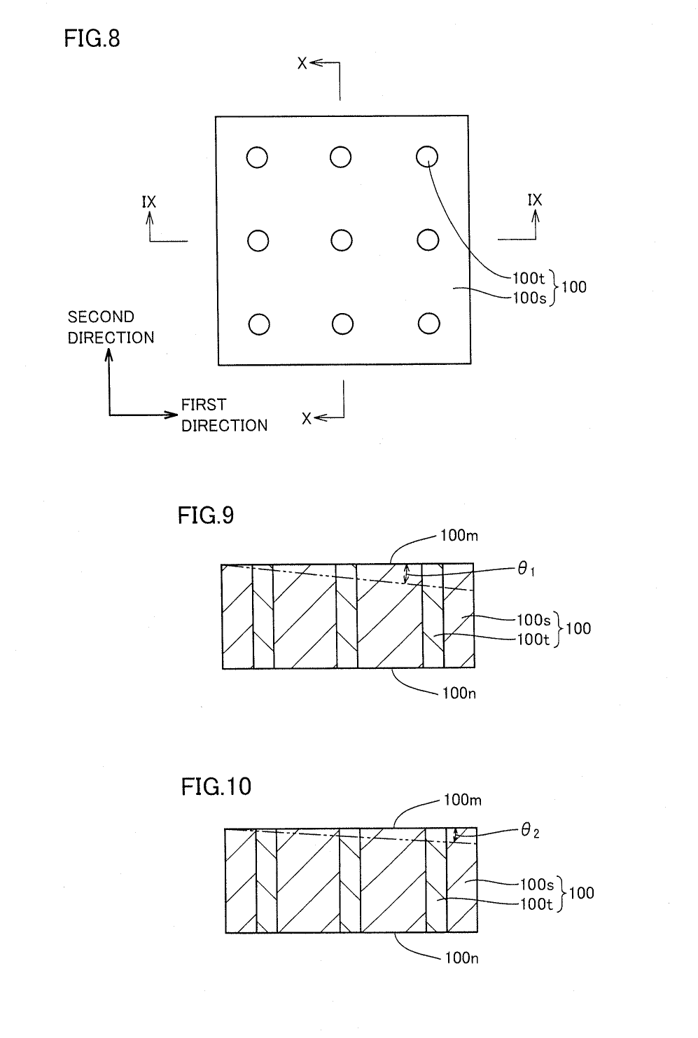

Referring to FIGS. 8 to 10, GaN crystal substrate 100 included in the group III nitride light-emitting device includes matrix crystal region 100s and c-axis-inverted crystal region 100t. Matrix crystal region 100s is a main crystal region constituting GaN crystal substrate 100, and has a lower dislocation density than c-axis-inverted crystal region 100t. C-axis-inverted crystal region 100t is a crystal region in which the <1-210> direction of the crystal is oriented identically to the <1-210> direction of the crystal in matrix crystal region 100s, and the <0001> direction of the crystal is inverted relative to that of matrix crystal region 100s. Here, matrix crystal region 100s and c-axis-inverted crystal region 100t in GaN crystal substrate 100 can be observed with a fluorescence microscope, and the crystal orientation of the crystal in these crystal regions can be measured in accordance with the convergent-beam electron diffraction method using a TEM (transmission electron microscope).

Here, the <1-210> direction is oriented identically means that the direction vector of the <1-210> direction of the crystal in c-axis-inverted crystal region 100t and the direction vector of the <1-210> direction of the crystal in matrix crystal region 100s are oriented substantially identically to each other, and a deviation between respective <1-210> directions of these crystal regions is less than 30°.

Further, the <0001> direction is inverted means that the direction vector of the <0001> direction of the crystal in c-axis-inverted crystal region 100t and the direction vector of the <0001> direction of the crystal in matrix crystal region 100s are oriented substantially opposite to each other, and a deviation between respective <0001> directions of these crystal regions is less than 30°.

GaN crystal substrate 100 is formed through growth and treatment in accordance with the facet growth method. Dislocations in the whole crystal substrate are collectively located in c-axis-inverted crystal region 100t and dislocations represented by vectors of opposite signs are coupled together. Thus, the dislocation density of matrix crystal region 100s is reduced. While the dislocation density of GaN crystal substrate 100 is not particularly limited, a lower dislocation density of GaN crystal substrate 100 is preferable for reducing the dislocation density of group III nitride semiconductor layer 200 to be grown on main surface 100m. For example, in matrix crystal region 100s, the dislocation density is preferably not more than 2×10⁷ cm⁻², and more preferably 1×10⁶ cm⁻². Here, the dislocation density of GaN crystal substrate 100 can be measured in accordance with the CL (cathode luminescence) method using an SEM (scanning electron microscope).

In GaN crystal substrate 100, the arrangement of matrix crystal region 100s and c-axis-inverted crystal region 100t is not particularly limited. However, in order to reduce the dislocation density of the GaN crystal substrate and grow a group III nitride crystal having a low dislocation density on the main surface of the GaN crystal substrate, it is preferable to arrange c-axis-inverted crystal region 100t in the form of dots on rectangular lattice points or triangular lattice points, with respect to matrix crystal region 100s, as seen from main surface 100m of GaN crystal substrate 100. In terms of the product yield, each dot of c-axis-inverted crystal region 100t preferably has a diameter of not less than 15 μm and not more than 100 μm, and the pitch between the dots is preferably not less than 100 μm and not more than 2000 μm. Further, matrix crystal region 100s and c-axis-inverted crystal region 100t are preferably formed to extend through GaN crystal substrate 100 from one main surface 100m to the other main surface 100n of the substrate.

Referring to FIGS. 1 to 5, on at least main surface 100m of GaN crystal substrate 100 on which matrix crystal region 100s and c-axis-inverted crystal region 100t appear, at least one group III nitride semiconductor layer 200 is grown. Accordingly, on matrix crystal region 100s of GaN crystal substrate 100, a matrix crystal region 200s of group III nitride semiconductor layer 200 that has the same crystal orientation as matrix crystal region 100s is formed and, on c-axis-inverted crystal region 100t of GaN crystal substrate 100, a c-axis-inverted crystal region 200t of group III nitride semiconductor layer 200 that has the same crystal orientation as c-axis-inverted crystal region 100t is formed. This is for the reason that group III nitride semiconductor layer 200 grows to have the crystal's physical properties of each region in main surface 100m of GaN crystal substrate 100.

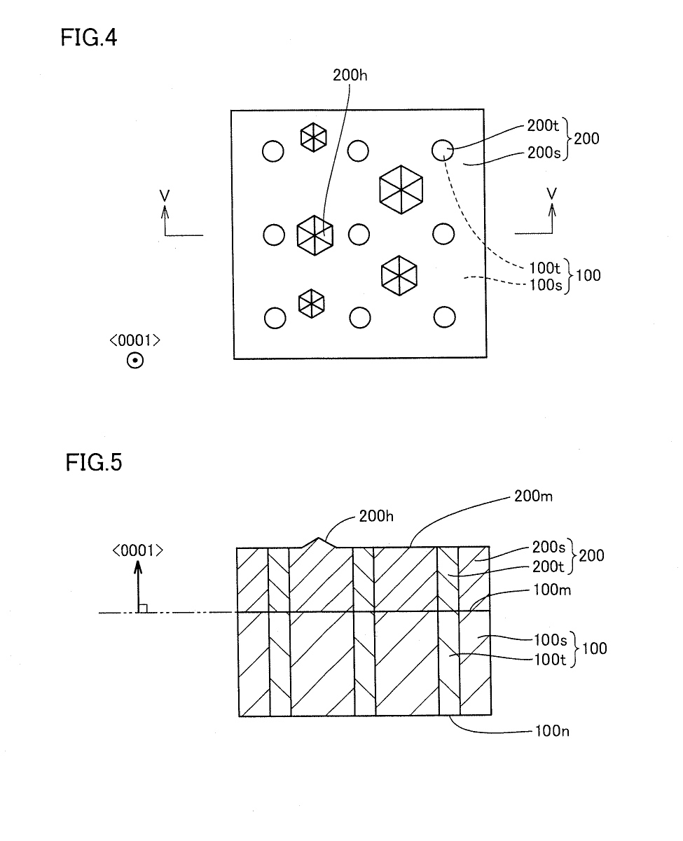

Here, referring to FIGS. 4 and 5, if absolute value |θ₁| of the off-angle component of the first direction and absolute value |θ₂| of the off-angle component of the second direction (namely the absolute value of the off-angle component of the <10-10> direction and the absolute value of the off-angle component of the <1-210> direction) are less than 0.3°, i.e., if group III nitride semiconductor layer 200 is grown on main surface 100m of GaN crystal substrate 100 where main surface 100m is substantially parallel with the {0001} plane, a protrusion 200h in the shape of a hexagonal pyramid whose apex has a large obtuse angle is formed in at least a part of matrix crystal region 200s in a main surface 200m of thus grown group III nitride semiconductor layer 200. Thus, group III nitride semiconductor layer 200 has main surface 200m with the deteriorated morphology, and accordingly has nonuniform physical properties. Here, protrusion 200h of main surface 200m of group III nitride semiconductor layer 200 can be observed with a differential interference microscope.

Referring to FIGS. 1 to 3, when absolute value |θ₁| of the off-angle component of the first direction (namely the absolute value of the off-angle component of one of the <10-10> direction and the <1-210> direction) is 0.03° or more, above-described protrusion 200h in the shape of a hexagonal pyramid is not formed on main surface 200m of group III nitride semiconductor layer 200. However, a depression 200r (as shown in FIG. 1, this depression 200r has the shape of a crescent for example in most cases) is formed in a part of matrix crystal region 200s that is adjacent, in the direction in which the {0001} plane has a maximum off angle from main surface 200m (this surface is substantially parallel with main surface 100m of GaN crystal substrate 100), to c-axis-inverted crystal region 200t of main surface 200m of group III nitride semiconductor layer 200. As absolute value IN of the off-angle component of the first direction is larger, the ratio of area Sr of depression 200r appearing on main surface 200m of group III nitride semiconductor layer 200 relative to area St of c-axis-inverted crystal region 100t appearing on main surface 100m of GaN crystal substrate 100 (the ratio will hereinafter be referred to as the area ratio of the depression) is accordingly larger. Thus, main surface 200m of group III nitride semiconductor layer 200 has the deteriorated morphology and the physical properties of the semiconductor layer are nonuniform. Here, depression 200r and its area Sr in main surface 200m of group III nitride semiconductor layer 200 can be observed and measured with a differential interference microscope. Further, c-axis-inverted crystal region 100t and its area St in main surface 100m of GaN crystal substrate 100 can be observed and measured with a fluorescence microscope.

In the case where absolute value |θ₂| of the off-angle component of the second direction (namely the absolute value of the off-angle component of the <1-210> direction in the case where the first direction is the <10-10> direction, or the absolute value of the off-angle component of the <10-10> direction in the case where the first direction is the <1-210> direction) is larger than 0.75×|θ₁, the main surface of group III nitride semiconductor layer 200 is wavy in shape and the composition of group III nitride semiconductor layer 200 is nonuniform. Thus, resultant group III nitride semiconductor layer 200 has nonuniform physical properties.

Therefore, in order to grow group III nitride semiconductor layer 200 having good morphology and uniform physical properties on main surface 100m of GaN crystal substrate 100 and thereby obtain a group III nitride semiconductor light-emitting device having excellent characteristics, it is necessary that off angle θ between main surface 100m and the {0001} plane of GaN crystal substrate 100 meets the following range. Specifically, an off-angle component of a first direction has an absolute value |θ₁| of not less than 0.03° and not more than 1.1° and an off-angle component of a second direction has an absolute value |θ₂| of not more than 0.75×|θ₁| (the range of the off angle will be referred to as Range Z1 hereinafter), where the first direction is one of the <10-10> direction and the <1-210> direction and the second direction is the other thereof. A preferred range is that absolute value |θ₁| of the off-angle component of the first direction is not less than 0.05° and not more than 0.86° and absolute value |θ₂| of the off-angle component of the second direction is not more than 0.5×|θ₁| (hereinafter referred to as Range Z2). A more preferred range is that absolute value |θ₁| of the off-angle component of the first direction is not less than 0.11° and not more than 0.76° and absolute value |θ₂| of the off-angle component of the second direction is not more than 0.375×|θ₁| (hereinafter referred to as Range Z3). A still more preferred range is that absolute value |θ₁| of the off-angle component of the first direction is not less than 0.2° and not more than 0.6° and absolute value |θ₂| of the off-angle component of the second direction is not more than 0.25×|θ₁| (hereinafter referred to as Range Z4). A particularly preferred range is that absolute value |θ₁| of the off-angle component of the first direction is not less than 0.3° and not more than 0.5° and absolute value |θ₂| of the off-angle component of the second direction is not more than 0.125×|θ₁| (hereinafter referred to as Range Z5).

Here, regarding off angle θ between main surface 100m of GaN crystal substrate 100 and the {0001}plane, absolute value |θ₁| of the off-angle component of the first direction and absolute value |θ₂| of the off-angle component of the second direction can be measured by means of x-ray diffraction by scanning the ω angle using the (0002) plane as a diffraction plane.

Further, in order to make smooth the flow of a material gas when the group III nitride semiconductor is grown on main surface 100m (front main surface) of GaN crystal substrate 100 and thereby grow a uniform group III nitride semiconductor layer, main surface 100m (front main surface) on which the crystal is to be grown preferably has a warp of not less than −20 μm and not more than 10 μm.

Further, in order to provide uniform contact between the opposite main surface 100n (rear main surface) which is opposite to the main surface on which the crystal is grown and the substrate holder and grow a uniform group III nitride semiconductor layer under uniform temperature control, main surface 100n (rear main surface) of GaN crystal substrate 100 preferably has a warp of not less than −20 μm and not more than 20 μm.

Here, the warp of main surface 100m (front main surface) and the warp of main surface 100n (rear main surface) can be measured in the following manner. Specifically, the difference of the level between the highest point and the lowest point of main surface 100m (front main surface) and main surface 100n (rear main surface) of GaN crystal substrate 100 having a predetermined size (diameter of 2 inches (5.08 cm) for example) can be measured by means of a laser-focus-type laser displacement sensor (LT-9010 (laser output unit) and LT-9500 (laser control unit) manufactured by Keyence Corporation), an XY position controller (CP-500 manufactured by COMS Co., Ltd.), and a high-speed analog voltage data collector (CA-800 manufactured by COMS Co., Ltd.). For this laser displacement sensor, a red semiconductor laser with a laser wavelength of 670 nm may be used.

Further, the warp is expressed with the plus (+) sign or the minus (−) sign in the following manner. GaN crystal substrate 100 is placed so that the surface to be measured is oriented upward. A warp protruding upward is represented with the plus (+) sign and a warp depressing downward is represented with the minus (−) sign.

Group III Nitride Semiconductor Layer

Referring to FIGS. 1 to 3, 6, and 7, at least one group III nitride semiconductor layer 200 included in group III nitride semiconductor light-emitting device 10 is not particularly limited, and may have a structure suitable for an intended type of the group III nitride semiconductor light-emitting device.

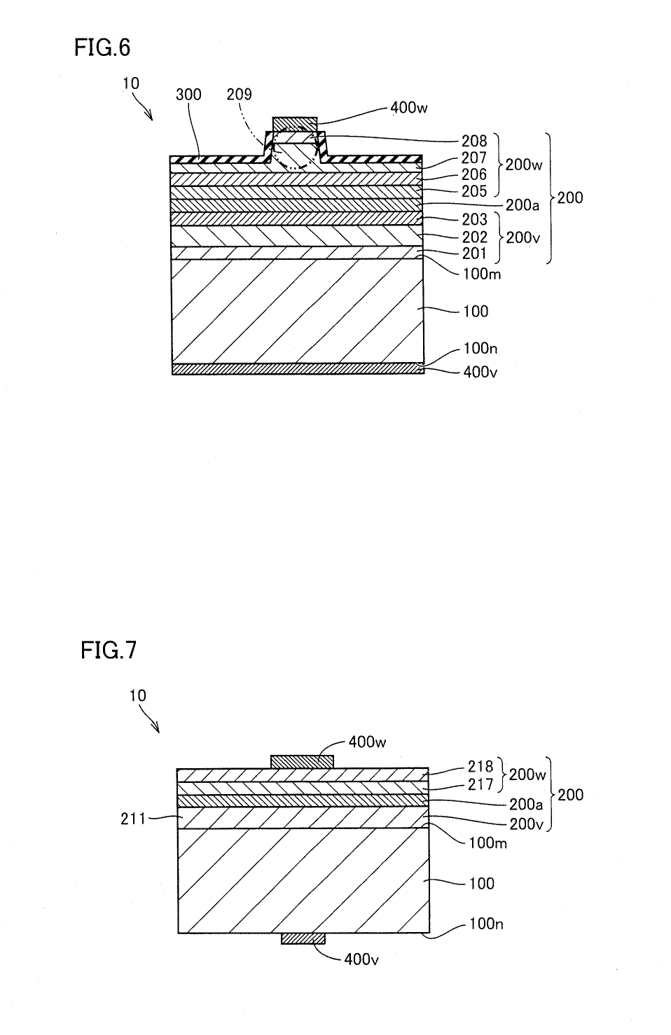

For example, referring to FIG. 6, in the case where group III nitride semiconductor light-emitting device 10 is an LD (laser diode), group III nitride semiconductor layer 200 may have an LD structure including a first-conductivity-type layer 200v, an active layer 200a, and a second-conductivity-type layer 200w. Referring to FIG. 7, in the case where group III nitride semiconductor light-emitting device 10 is an LED (light-emitting diode), group III nitride semiconductor layer 200 may have an LED structure including a first-conductivity-type layer 200v, an active layer 200a, and a second-conductivity-type layer 200w.

In group III nitride semiconductor light-emitting device 10, each layer of group III nitride semiconductor layer 200 and GaN crystal substrate 100 may or may not have its matrix crystal region and c-axis-inverted crystal region. FIGS. 6 and 7, however, are not illustrated to identify the matrix crystal region and the c-axis-inverted crystal region.

Referring to FIG. 6, group III nitride semiconductor light-emitting device 10 which is an LD includes group III nitride semiconductor layer 200 on main surface 100m (front main surface) of GaN crystal substrate 100. Specifically, group III nitride semiconductor layer 200 includes: an n-type GaN layer 201, an n-type Alₓ₁Ga₁₋ₓ₁N cladding layer 202, and n-type GaN optical waveguide layer 203, which are included in first-conductivity-type layer 200v; an MQW (multiple quantum well structure) active layer 200a; a p-type Alₓ₂Ga₁₋ₓ₂N cap layer 205, a p-type GaN optical waveguide layer 206, a p-type Alₓ₃Ga₁₋ₓ₃N cladding layer 207, and a p-type GaN contact layer 208, which are included in second-conductivity-type layer 200w. These layers are arranged in this order. Here, the subscripts x1, x2, and x3 on the lower right of the chemical symbols each represent a real number larger than zero and smaller than one.

P-type GaN contact layer 208 and p-type Alₓ₃Ga₁₋ₓ₃N cladding layer 207 are each partially removed by etching to form a ridge portion 209 that is constituted of a part of p-type GaN contact layer 208 and a part of p-type Alₓ₃Ga₁₋ₓ₃N cladding layer 207. On the surface of p-type GaN contact layer 208 and the surface of p-type Alₓ₃Ga₁₋ₓ₃N cladding layer 207 that are exposed by the above-described etching, an SiO₂ layer which is an insulating layer 300 is disposed. On p-type GaN contact layer 208 of ridge portion 209, a second electrode 400w is disposed. On main surface 100n (rear main surface) of GaN crystal substrate 100, a first electrode 400v is disposed.

Referring to FIG. 7, group III nitride semiconductor light-emitting device 10 which is an LED includes group III nitride semiconductor layer 200 on main surface 100m (front main surface) of GaN crystal substrate 100. Specifically, group III nitride semiconductor layer 200 includes: an n-type GaN layer 211 which is first-conductivity-type layer 200v; an MQW (multiple quantum well structure) active layer 200a; and a p-type Alₓ₄Ga₁₋ₓ₄N block layer 217 and a p-type GaN contact layer 218 that are included in second-conductivity-type layer 200w. These layers are arranged in this order. Here, the subscript x4 on the lower right of the chemical symbol represents a real number larger than zero and smaller than one. On p-type GaN contact layer 218, a second electrode 400w is disposed. On main surface 100n (rear main surface) of GaN crystal substrate 100, a first electrode 400v is disposed.

[Method for Manufacturing Group III Nitride Semiconductor Light-Emitting Device]

Referring to FIGS. 6, 7, and 11, a method for manufacturing a group III nitride semiconductor light-emitting device in the present embodiment includes the step S1 of preparing GaN crystal substrate 100, and the step S2 of growing at least one group III nitride semiconductor layer 200 on main surface 100m of GaN crystal substrate 100.

Step of Preparing GaN Crystal Substrate

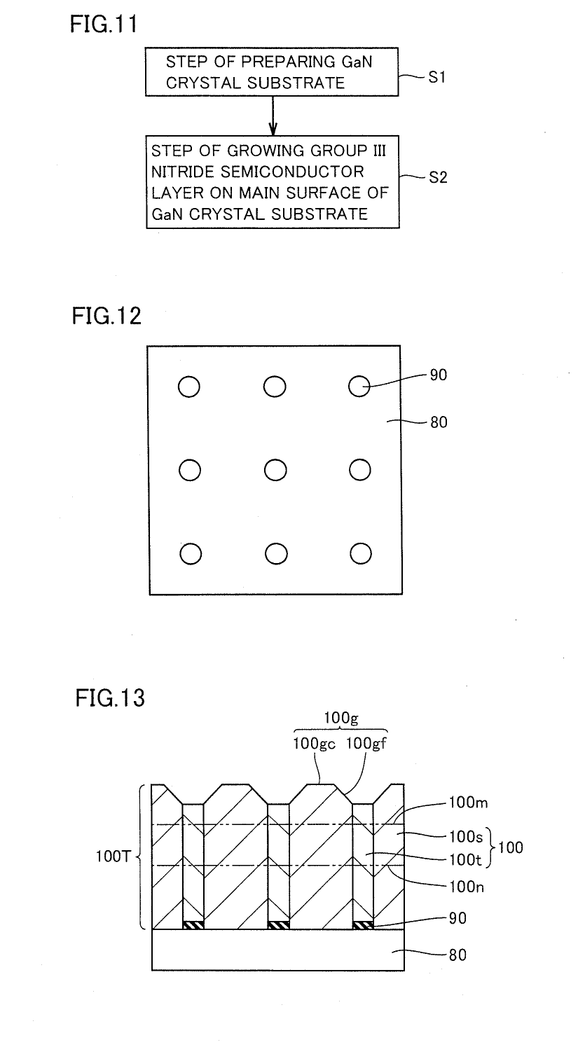

Referring to FIGS. 11 to 13, step S1 of preparing GaN crystal substrate 100 includes a sub step of forming a mask 90 on a base substrate 80 (FIG. 12), and a sub step of forming a GaN crystal substrate by growing and processing a GaN crystal on base substrate 80 on which mask 90 is formed (FIG. 13).

Referring to FIG. 12, in the sub step of forming mask 90 on base substrate 80, base substrate 80 is not particularly limited as long as a GaN crystal can be grown on the main surface of the base substrate. In order to enhance the crystallinity of the grown GaN crystal, however, a sapphire substrate, an SiC substrate, a GaAs substrate, or a template substrate in which a GaN crystal layer is formed on any of these substrates is suitably used. Mask 90 is not particularly limited as long as it suppresses growth of the GaN crystal for forming the c-axis-inverted crystal region of the GaN crystal on the main surface of the mask, and an SiO₂ layer, an Si₃N₄ layer or the like is suitably used. The method for forming mask 90 is not particularly limited, and sputtering, CVD (chemical vapor deposition), or the like is suitably used.

Further, arrangement of mask 90 on base substrate 80 is not particularly limited. In order to effectively reduce the dislocation density of the grown GaN crystal, however, mask 90 is preferably arranged in the form of dots on rectangular lattice points or triangular lattice points on the main surface of base substrate 80. In terms of the product yield, each dot of mask 90 preferably has a diameter of not less than 15 μm and not more than 100 μm, and the pitch between the dots is preferably not less than 100 μm and not more than 2000 μm.

Referring to FIG. 13, in the sub step of forming GaN crystal substrate 100 by growing and processing a GaN crystal 100T on base substrate 80 on which mask 90 is formed, the method for growing GaN crystal 100T is not particularly limited, and the vapor phase method such as HVPE (hydride vapor phase epitaxy), MOCVD (metal organic chemical vapor deposition), MBE (molecular beam epitaxy), or sublimation method, or the liquid phase method such as flux method, for example, is used. HVPE is preferred since it provides a high-speed crystal growth.

The above-described method is used to grow GaN crystal 100T on base substrate 80 on which mask 90 is formed. Then, on base substrate 80 on which mask 90 is not formed, matrix crystal region 100s is formed. On mask 90, c-axis-inverted crystal region 100t is formed. On a crystal growth surface 100g of GaN crystal 100T, a facet 100gf having a plane orientation other than a {0001} plane 100gc is formed. The facet growth method according to which GaN crystal 100T is grown while this facet 100gf is maintained is used to collect, in c-axis-inverted crystal region 100t, dislocations in the whole GaN crystal 100T, so that dislocations represented by vectors of opposite signs are coupled together. Thus, the dislocation density of matrix crystal region 100s is reduced.

GaN crystal 100T thus grown is sliced and processed along a plane having a predetermined off angle θ (off-angle component θ₁ of the first direction and off-angle component θ₂ of the second direction) with respect to the {0001} plane. Accordingly, the GaN crystal substrate having main surfaces 100m, 100n with a predetermined off angle θ (off-angle component θ₁ of the first direction and off-angle component θ₂ of the second direction) with respect to the {0001} plane is formed. Here, other than the above-described method for forming off angle θ, a method for forming off angle θ by grinding or polishing, or a method that grows a GaN crystal on base substrate 80 having off angle θ and slices and processes it along a plane parallel with the main surface of the base substrate may be used.

Step of Growing Group III Nitride Semiconductor Layer

Referring to FIGS. 6, 7, and 11, in step S2 of growing at least one group III nitride semiconductor layer 200 on main surface 100m of GaN crystal substrate 100, the method for growing group III nitride semiconductor layer 200 is not particularly limited, and the vapor phase method such as MOCVD, MBE, HYPE, or sublimation method, or the liquid phase method such as flux method, for example, is used. MOCVD is preferred since it provides a high precision in adjustment of the chemical composition and the thickness of group III nitride semiconductor layer 200.

Manufacture of Group III Nitride Semiconductor Light-Emitting Device as LD

Referring to FIG. 6, in the above-described step of growing group III nitride semiconductor layer 200, an LD (laser diode) structure is formed that includes, in group III nitride semiconductor layer 200, first-conductivity-type layer 200v, active layer 200a, and second-conductivity-type layer 200w, and accordingly group III nitride semiconductor light-emitting device 10 which is an LD is manufactured.

The method for manufacturing group III nitride semiconductor light-emitting device 10 which is an LD is not particularly limited. The device may be manufactured for example in the following way.

1. Preparation of GaN Crystal Substrate

GaN crystal substrate 100 having main surfaces 100m, 100n with predetermined off angle θ relative to the {0001} plane is prepared.

2. Growth of Group III Nitride Semiconductor Layer

Then, on main surface 100m (front main surface) of GaN crystal substrate 100 described above, MOCVD is performed to epitaxially grow group III nitride semiconductor layer 200. Specifically, n-type GaN layer 201 doped with Si, n-type Alₓ₁Ga₁₋ₓ₁N cladding layer 202 doped with Si, and n-type GaN optical waveguide layer 203 doped with Si, which are included in first-conductivity-type layer 200v; MQW (multiple quantum well) structure active layer 200a made up of an un-doped In_{y1}Ga_{1-y1}N layer and an un-doped In_{y2}Ga_{1-y2}N layer; p-type Alₓ₂Ga₁₋ₓ₂N cap layer 205 doped with Mg, p-type GaN optical waveguide layer 206 doped with Mg, p-type Alₓ₃Ga₁₋ₓ₃N cladding layer 207 doped with Mg, and p-type GaN contact layer 208 doped with Mg, which are included in second-conductivity-type layer 200w are successively grown epitaxially. Here, the subscripts x1, x2, x3, y1, and y2 on the lower right of the chemical symbols each represent a real number larger than zero and smaller than one.

3. Fabrication of Device

Next, on the whole main surface of p-type GaN contact layer 208, an SiO₂ film is formed by CVD. After this, on this SiO₂ film, a resist pattern (not shown) of a predetermined shape adapted to the shape of ridge portion 209 is formed by lithography. The resist pattern is used as a mask and wet etching is performed using a hydrofluoric-acid-based etchant for example to etch the SiO₂ film so that it has the shape corresponding to ridge portion 209. Here, this SiO₂ film may be formed by means of vacuum vapor deposition, sputtering, or the like. For etching of the SiO₂ film, RIE (reactive ion etching) using an etching gas containing fluorine may also be used.

Next, this SiO₂ film is used as a mask and etching is performed in accordance with RIE to etch the layers from the surface of p-type GaN contact layer 208 to a predetermined depth in the direction of the thickness of p-type Alₓ₃Ga₁₋ₓ₃N cladding layer 207 and thereby form ridge portion 209 extending in the <10-10> direction. This ridge portion 209 has a width of 2 μm. As the etching gas for this RIE, a chlorine-based gas is used.

Next, the SiO₂ film used as the etching mask is etched away. After this, CVD, vacuum vapor deposition, sputtering or the like for example is performed to form, on the whole main surface, insulating layer 300 such as SiO₂ layer for example. This insulating layer 300 is provided for electrical insulation and surface protection.

Next, lithography is performed to form a resist pattern (not shown) that covers the surface of insulating layer 300 of the region except for the region where the second electrode is to be formed. Subsequently, the resist pattern is used as a mask to etch insulating layer 300 and thereby form an opening.

Next, with the resist pattern left as it is, vacuum vapor deposition for example is performed to successively form, on the whole main surface, a Pd film, a Pt film, and an Au film for example. After this, the resist pattern is removed together with the Pd film, the Pt film, and the Au film formed on the pattern (lift off). In this way, second electrode 400w is formed that contacts p-type GaN contact layer 208 through the opening of insulating layer 300.

Next, in order to facilitate division into chips, the main surface on which second electrode 400w is formed is attached to a polish holder, and GaN crystal substrate 100 is thinned by polishing.

Next, on main surface 100n (rear main surface) of GaN crystal substrate 100, vacuum vapor deposition for example is performed to successively form a Ti film, a Pt film, and an Au film for example and thereby form first electrode 400v of the Ti/Pt/Au structure.

Next, GaN crystal substrate 100 on which group III nitride semiconductor layer 200 having the laser structure is formed in the above-described manner is scribed by cleaving into a laser bar so that both end faces of a resonator are formed. Then, these resonator's end faces are coated, and thereafter this laser bar is scribed again by cleaving into chips. In this way, group III nitride semiconductor light-emitting device 10 which is an LD is manufactured.

Manufacture of Group III Nitride Semiconductor Light-Emitting Device as LED

Referring to FIG. 7, in the above-described step of growing group III nitride semiconductor layer 200, an LED (light-emitting diode) structure is formed that includes, in group III nitride semiconductor layer 200, first-conductivity-type layer 200v, active layer 200a, and second-conductivity-type layer 200w, and accordingly group III nitride semiconductor light-emitting device 10 which is an LED is manufactured.

The method for manufacturing group III nitride semiconductor light-emitting device 10 which is an LED is not particularly limited. The device may be manufactured for example in the following way.

I. Preparation of GaN Crystal Substrate

GaN crystal substrate 100 having main surfaces 100m, 100n with predetermined off angle θ relative to the {0001} plane is prepared.

2. Growth of Group III Nitride Semiconductor Layer

Then, on main surface 100m (front main surface) of GaN crystal substrate 100 described above, MOCVD is performed to epitaxially grow group III nitride semiconductor layer 200. Specifically, n-type GaN layer 211 doped with Si which is first-conductivity-type layer 200v; MQW (multiple quantum well) structure active layer 200a made up of an un-doped In_{y3}Ga_{1-y3}N layer and an un-doped GaN layer; and p-type Alₓ₄Ga₁₋ₓ₄N block layer 217 doped with Mg and p-type GaN contact layer 218 doped with Mg, which are included in second-conductivity-type layer 200w, are successively grown epitaxially. Here, the subscripts x4 and y3 on the lower right of the chemical symbols each represent a real number larger than zero and smaller than one.

3. Fabrication of Device

Next, first electrode 400v is formed on at least a part of main surface 100n (rear main surface) of GaN crystal substrate 100, second electrode 400w is formed on at least a part of the main surface of p-type GaN contact layer 218, and they are further processed into a chip. In this way, group III nitride semiconductor light-emitting device 10 which is an LED is manufactured.

### Example A

### 1. Preparation of GaN Crystal Substrate

GaN crystal substrates of 17 different types having a diameter of two inches (5.08 cm) and a thickness of 400 μm were prepared (Examples AR-1 to AR-3 and Examples A-1 to A-14). The GaN crystal substrates each included a matrix crystal region and a c-axis-inverted crystal region. On the front main surface of the substrate, the c-axis-inverted crystal region was arranged in the form of dots on square lattice points. The dots had a diameter of 60 μm and the pitch between the dots was 1000 μm. The front main surface had a predetermined off angle θ with respect to the {0001} plane, and the front main surface and the rear main surface had a predetermined warp. In Example A, the <10-10> direction was defined as the first direction of off angle θ and the <1-210> direction was defined as the second direction of off angle θ.

Here, regarding off angle θ between the front main surface of the GaN crystal substrate and the {0001} plane, absolute value |θ₁| of the off-angle component of the first direction and absolute value |θ₂| of the off-angle component of the second direction were measured by means of x-ray diffraction by scanning the co angle using the (0002) plane as a diffraction plane. Further, the warp of the front main surface and the warp of the rear main surface were each measured by determining the level difference between the highest point and the lowest point of each of the front main surface and the rear main surface of the GaN crystal substrate, by means of a laser-focus-type laser displacement sensor (LT-9010 (laser output unit) and LT-9500 (laser control unit) manufactured by Keyence Corporation), an XY position controller (CP-500 manufactured by COMS Co., Ltd.), and a high-speed analog voltage data collector (CA-800 manufactured by COMS Co., Ltd.). For this laser displacement sensor, a red semiconductor laser with a laser wavelength of 670 nm was used. Here, the warp is expressed with the plus (+) sign or the minus (−) sign in the following manner. The GaN crystal substrate is placed so that the surface to be measured is oriented upward. A warp protruding upward is represented with the plus (+) sign and a warp depressing downward is represented with the minus (−) sign.

Regarding the GaN crystal substrates of the 17 different types each, absolute value |θ₁| of the off-angle component of the <10-10> direction, absolute value |θ₂| of the off-angle component of the <1-210> direction, the warp of the front main surface, and the warp of the rear main surface were as follows. Regarding the GaN crystal substrate of Example AR-1, they were 1.00°, 0.90°, −11.4 μm, and −12.5 μm, respectively. Regarding the GaN crystal substrate of Example AR-2, they were 0.60°, 0.60°, −10.5 μm, and −12.4 μm, respectively. Regarding the GaN crystal substrate of Example AR-3, they were 0.10°, 0.09°, −14.4 μm, and −10.5 μm, respectively. Regarding the GaN crystal substrate of Example A-1, they were 1.10°, 0.80°, −18.2 μm, and −15.8 μm, respectively. Regarding the GaN crystal substrate of Example A-2, they were 0.03°, 0.02°, −15.2 μm, and −16.7 μm, respectively. Regarding the GaN crystal substrate of Example A-3, they were 0.86°, 0.42°, 5.6 μm, and −8.5 μm, respectively. Regarding the GaN crystal substrate of Example A-4, they were 0.05°, 0.02°, 5.6 μm, and −5.8 μm, respectively. Regarding the GaN crystal substrate of Example A-5, they were 0.76°, 0.27°, −12.4 μm, and 7.8 μm, respectively. Regarding the GaN crystal substrate of Example A-6, they were 0.11°, 0.04°, −11.6 μm, and 16.8 μm, respectively. Regarding the GaN crystal substrate of Example A-7, they were 0.59°, 0.14°, −18.4 μm, and 14.7 μm, respectively. Regarding the GaN crystal substrate of Example A-8, they were 0.20°, 0.04°, 8.9 μm, and 11.9 μm, respectively. Regarding the GaN crystal substrate of Example A-9, they were 0.48°, 0.11°, −9.6 μm, and 17.8 μm, respectively. Regarding the GaN crystal substrate of Example A-10, they were 0.31°, 0.07°, 4.5 μm, and −18.6 μm, respectively. Regarding the GaN crystal substrate of Example A-11, they were 0.60°, 0.04°, −6.2 μm, and 3.4 μm, respectively. Regarding the GaN crystal substrate of Example A-12, they were 0.21°, 0.01°, 9.5 μm, and 8.9 μm, respectively. Regarding the GaN crystal substrate of Example A-13, they were 0.49°, 0.03°, −7.8 μm, and −11.2 μm, respectively. Regarding the GaN crystal substrate of Example A-14, they were 0.30°, 0.02°, −8.2 μm, and 10.3 μm, respectively. The results are summarized in Table 1.

2. Growth of Group III Nitride Semiconductor Layer

Then, on the front main surface of the GaN crystal substrates of the 17 different types each, MOCVD was performed to epitaxially grow a group III nitride semiconductor layer. Specifically, an n-type GaN layer doped with Si and having a thickness of 0.05 μm, an n-type Al_{0.08}Ga_{0.92}N cladding layer doped with Si and having a thickness of 1.0 μm, an n-type GaN optical waveguide layer doped with Si and having a thickness of 0.1 μm, a 5-cycle MQW (multiple quantum well) structure active layer made up of an un-doped In_{0.15}Ga_{0.85}N layer having a thickness of 3 nm and an un-doped In_{0.03}Ga_{0.97}N layer having a thickness of 6 nm, a p-type Al_{0.2}Ga_{0.8}N cap layer doped with Mg and having a thickness of 10 nm, a p-type GaN optical waveguide layer doped with Mg and having a thickness of 0.1 μm, a p-type Al_{0.08}Ga_{0.92}N cladding layer doped with Mg and having a thickness of 0.3 μm, and a p-type GaN contact layer doped with Mg and having a thickness of 0.05 μm were successively grown epitaxially.

The surface of the semiconductor layer-stack wafer thus obtained was observed with a differential interference microscope. It was observed that the group III nitride semiconductor epitaxial layer epitaxially grown in the <10-10> direction and the <12-10> direction was recessed (depressed) in the vicinity of the c-axis-inverted crystal region. From area St of the c-axis-inverted crystal region appearing on the front main surface of the GaN crystal substrate that was measured with a fluorescence microscope, and area Sr of the depression of the group III nitride semiconductor epitaxial layer that was measured with the differential interference microscope, the area ratio of the depression (the ratio of area Sr of the depression to area St of the c-axis-inverted crystal region) was calculated.

Next, the distribution of the emission wavelength of the obtained semiconductor layer-stack wafer was evaluated by the PL (photoluminescence) method. Specifically, a laser beam (He—Cd laser beam with a peak wavelength of 325 nm) having a greater energy than the bandgap of any layer of the group III nitride semiconductor layer was applied at a pitch of 1 mm over the whole main surface on the group III nitride semiconductor layer side of the semiconductor layer-stack wafer having a diameter of two inches (5.08 cm). For the excited emission, the distribution of the emission wavelength within the main surface (difference between the maximum wavelength and the minimum wavelength) was measured.

3. Fabrication of Device

Next, on the whole main surface of the p-type GaN contact layer, an SiO₂ film having a thickness of 0.1 μm was formed by CVD. After this, on this SiO₂ film, a resist pattern of a predetermined shape adapted to the shape of the ridge portion was formed by lithography. The resist pattern was used as a mask and wet etching was performed using a hydrofluoric-acid-based etchant to etch the SiO₂ film so that it had the shape corresponding to the ridge portion.

Next, this SiO₂ film was used as a mask and etching was performed in accordance with RIE to etch the layers from the surface of the p-type GaN contact layer to a predetermined depth in the direction of the thickness of the p-type Al_{0.08}Ga_{0.92}N cladding layer and thereby form the ridge portion extending in the <10-10> direction. This ridge portion had a width of 2 μm. As the etching gas for this RIE, a chlorine-based gas was used.

Next, the SiO₂ film used as the etching mask was etched away. After this, CVD was performed to form, on the whole main surface, an insulating layer, specifically an SiO₂ layer having a thickness of 0.3 μm. This insulating layer was provided for electrical insulation and surface protection.

Next, lithography was performed to form a resist pattern covering the surface of the insulating layer of the region except for the region where the second electrode was to be formed. Subsequently, the resist pattern was used as a mask to etch the insulating layer and thereby form an opening.

Next, with the resist pattern left as it was, vacuum vapor deposition was performed to successively form, on the whole main surface, a Pd film, a Pt film, and an Au film. After this, the resist pattern was removed together with the Pd film, the Pt film, and the Au film formed on the pattern (lift off). In this way, the second electrode contacting the p-type GaN contact layer was formed through the opening of the insulating layer. Here, respective thicknesses of the Pd film, Pt film, and Au film constituting the second electrode were 10 nm, 100 nm, and 300 nm, respectively.

Next, in order to facilitate division into chips, the main surface on which the second electrode was formed was attached to a polish holder, and thereafter the GaN substrate was polished using a slurry containing an SiC abrasive having an average grain size of 30 μm, until the thickness 400 μm of the substrate became 100 μm.

Next, on the rear main surface of the GaN crystal substrate, vacuum vapor deposition was performed to successively form a Ti film, a Pt film, and an Au film and thereby form the first electrode of the Ti/Pt/Au structure. Here, the Ti film, Pt film, and Au film constituting the first electrode had respective thicknesses of 10 nm, 50 nm, and 100 nm.

Next, the GaN substrate on which the laser structure was formed in the above-described manner was scribed by cleaving into a laser bar so that both end faces of a resonator were formed. Then, these resonator's end faces were coated, and thereafter this laser bar was scribed again by cleaving into chips. In this way, from the semiconductor layer-stack wafers of respective types each, 100 LD chips were obtained, namely total 1700 LD chips were obtained from semiconductor layer-stack wafers of 17 different types.

For the 100 LD chips of each type, whether or not the laser chip emitted light was examined. The LD chip emitting light was accepted, and the ratio of accepted chips was calculated.

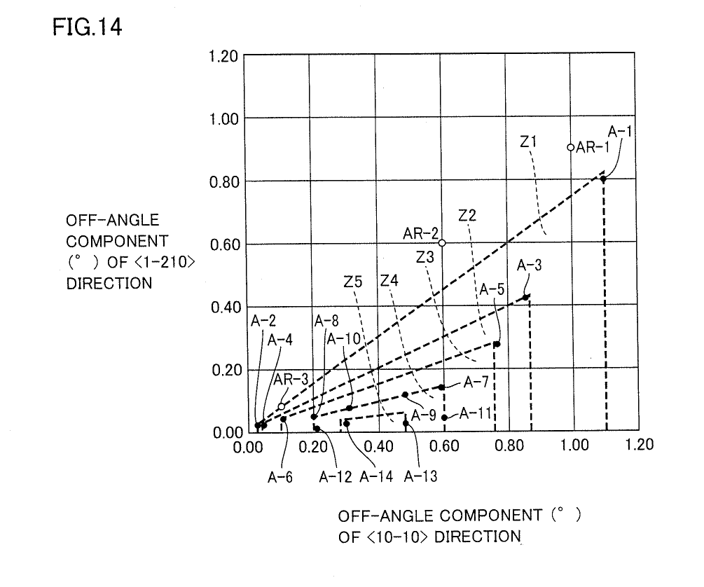

For the LDs of the 17 different types each, the area ratio of the depression, the distribution of the emission wavelength within the main surface, and the ratio of accepted chips were as follows. Regarding the LD of Example AR-1, they were 1.72, 22 nm, and 43%, respectively. Regarding the LD of Example AR-2, they were 1.46, 22 nm, and 44%, respectively. Regarding the LD of Example AR-3, they were 1.40, 18 nm, and 49%, respectively. Regarding the LD of Example A-1, they were 0.70, 12 nm, and 78%, respectively. Regarding the LD of Example A-2, they were 0.64, 12 nm, and 78%, respectively. Regarding the LD of Example A-3, they were 0.51, 9 nm, and 82%, respectively. Regarding the LD of Example A-4, they were 0.52, 9 nm, and 81%, respectively. Regarding the LD of Example A-5, they were 0.34, 8 nm, and 85%, respectively. Regarding the LD of Example A-6, they were 0.38, 8 nm, and 83%, respectively. Regarding the LD of Example A-7, they were 0.19, 7 nm, and 92%, respectively. Regarding the LD of Example A-8, they were 0.20, 7 nm, and 90%, respectively. Regarding the LD of Example A-9, they were 0.18, 7 nm, and 91%, respectively. Regarding the LD of Example A-10, they were 0.11, 7 nm, and 92%, respectively. Regarding the LD of Example A-11, they were 0.21, 4 nm, and 94%, respectively. Regarding the LD of Example A-12, they were 0.18, 4 nm, and 93%, respectively. Regarding the LD of Example A-13, they were 0.06, 4 nm, and 95%, respectively. Regarding the LD of Example A-14, they were 0.06, 4 nm, and 94%, respectively. The results are summarized in Table 1. Further, regarding the main surface of the GaN crystal substrate of the LD in each of Examples AR-1 to AR-3 and Examples A-1 to A-14, absolute value |θ₁| of the off-angle component of the <10-10> direction defined as the first direction and absolute value |θ₂| of the off-angle component of the <1-210> direction defined as the second direction are shown in the graph of FIG. 14.

TABLE 1

| | physical properties of substrate | | | | | | | | | | |
|---|---|---|---|---|---|---|---|---|---|---|---|
| | | | off angle θ | | | | | | | | |
| | | | absolute value | absolute value | | | | | | | |
| | | | \|θ₁\| of off-angle | \|θ₂\| of off-angle | warp of main | | characteristics of device | | | | |
| | | | component of | component of | surface | | | | distribution of | | |
| | c-axis-inverted | | <10-10> | <1-210> | front | rear | | | emission | | |
| | crystal region | | direction, i.e., | direction, i.e., | main | main | | area | wavelength | ratio of | (note:) |
| Example | diameter | pitch | first direction | second direction | surface | surface | | ratio of | within main | accepted | range of |
| A | (μm) | (μm) | (°) | (°) | (μm) | (μm) | type | depression | surface (nm) | chips (%) | off angle |
| Example | 60 | 1000 | 1.00 | 0.90 | −11.4 | −12.5 | LD | 1.72 | 22 | 43 | out of Z1 |
| AR-1 | | | | | | | | | | | |
| Example | 60 | 1000 | 0.60 | 0.60 | −10.5 | −12.4 | LD | 1.46 | 22 | 44 | out of Z1 |
| AR-2 | | | | | | | | | | | |
| Example | 60 | 1000 | 0.10 | 0.09 | −14.4 | −10.5 | LD | 1.40 | 18 | 49 | out of Z1 |
| AR-3 | | | | | | | | | | | |
| Example | 60 | 1000 | 1.10 | 0.80 | −18.2 | −15.8 | LD | 0.70 | 12 | 78 | Z1 |
| A-1 | | | | | | | | | | | |
| Example | 60 | 1000 | 0.03 | 0.02 | −15.2 | −16.7 | LD | 0.64 | 12 | 78 | Z1 |
| A-2 | | | | | | | | | | | |
| Example | 60 | 1000 | 0.86 | 0.42 | 5.6 | −8.5 | LD | 0.51 | 9 | 82 | Z2 |
| A-3 | | | | | | | | | | | |
| Example | 60 | 1000 | 0.05 | 0.02 | 5.6 | −5.8 | LD | 0.52 | 9 | 81 | Z2 |
| A-4 | | | | | | | | | | | |
| Example | 60 | 1000 | 0.76 | 0.27 | −12.4 | 7.8 | LD | 0.34 | 8 | 85 | Z3 |
| A-5 | | | | | | | | | | | |
| Example | 60 | 1000 | 0.11 | 0.04 | −11.6 | 16.8 | LD | 0.38 | 8 | 83 | Z3 |
| A-6 | | | | | | | | | | | |
| Example | 60 | 1000 | 0.59 | 0.14 | −18.4 | 14.7 | LD | 0.19 | 7 | 92 | Z4 |
| A-7 | | | | | | | | | | | |
| Example | 60 | 1000 | 0.20 | 0.04 | 8.9 | 11.9 | LD | 0.20 | 7 | 90 | Z4 |
| A-8 | | | | | | | | | | | |
| Example | 60 | 1000 | 0.48 | 0.11 | −9.6 | 17.8 | LD | 0.18 | 7 | 91 | Z4 |
| A-9 | | | | | | | | | | | |
| Example | 60 | 1000 | 0.31 | 0.07 | 4.5 | −18.6 | LD | 0.11 | 7 | 92 | Z4 |
| A-10 | | | | | | | | | | | |
| Example | 60 | 1000 | 0.60 | 0.04 | −6.2 | 3.4 | LD | 0.21 | 4 | 94 | Z4 |
| A-11 | | | | | | | | | | | |
| Example | 60 | 1000 | 0.21 | 0.01 | 9.5 | 8.9 | LD | 0.18 | 4 | 93 | Z4 |
| A-12 | | | | | | | | | | | |
| Example | 60 | 1000 | 0.49 | 0.03 | −7.8 | −11.2 | LD | 0.06 | 4 | 95 | Z5 |
| A-13 | | | | | | | | | | | |
| Example | 60 | 1000 | 0.30 | 0.02 | −8.2 | 10.3 | LD | 0.06 | 4 | 94 | Z5 |
| A-14 | | | | | | | | | | | |

As clearly seen from Table 1 and FIG. 14, in the case where the group III nitride semiconductor light-emitting devices functioning as LD had off angle θ between the main surface of the GaN crystal substrate and the {0001} plane that met the condition that absolute value |θ₁| of the off-angle component of the <10-10> direction defined as the first direction and absolute value |θ₂| of the off-angle component of the <1-210> direction defined as the second direction were within Range Z1 (0.03°≦|θ₁|≦1.1° and |θ₂|≦0.75×|θ₁|), the area ratio of the depression was low, the distribution of the emission wavelength within the main surface was small, and the ratio of accepted chips was high. The effect that the area ratio of the depression was decreased, the distribution of the emission wavelength within the main surface was reduced, and the ratio of accepted chips was increased was greater in the case where absolute value |θ₁| of the off-angle component of the <10-10> direction defined as the first direction and absolute value |θ₂| of the off-angle component of the <1-210> direction defined as the second direction were within Range Z2 (0.05°≦|θ₁|≦0.86° and |θ₂|≦0.5×|θ₁|), more greater in the case where they were within Range Z3 (0.11°≦|θ₁|≦0.76° and |θ₂|≦0.375×|θ₁|), still more greater in the case where they were within Range Z4 (0.2°≦|θ₁|≦0.6° and |θ₂≦0.25×|θ₁|), and further greater in the case where they were within Range Z5 (0.3°≦|θ₁|≦0.5° and |θ₂|≦0.125×|θ₁|).

### Example B

1. Preparation of GaN Crystal Substrate

GaN crystal substrates of 17 different types were prepared in a similar manner to Example A, except that the <1-210> direction was defined as the first direction of off angle θ and the <10-10> direction was defined as the second direction of off angle θ.

Regarding each of the GaN crystal substrates of 17 different types, absolute value |θ₂| of the off-angle component of the <10-10> direction, absolute value |θ₁| of the off-angle component of the <1-210> direction, the warp of the front main surface, and the warp of the rear main surface were as follows. Regarding the GaN crystal substrate of Example BR-1, they were 0.95°, 0.99°, 11.9 μm, and 11.9 μm, respectively. Regarding the GaN crystal substrate of Example BR-2, they were 0.59°, 0.66°, −9.6 μm, and 4.5 μm, respectively. Regarding the GaN crystal substrate of Example BR-3, they were 0.10°, 0.09°, 7.8 μm, and 4.5 μm, respectively. Regarding the GaN crystal substrate of Example B-1, they were 0.78°, 1.08°, 8.9 μm, and 7.8 μm, respectively. Regarding the GaN crystal substrate of Example B-2, they were 0.02°, 0.03°, −11.6 μm, and 17.8 μm, respectively. Regarding the GaN crystal substrate of Example B-3, they were 0.41°, 0.84°, 4.5 μm, and 14.7 μm, respectively. Regarding the GaN crystal substrate of Example B-4, they were 0.02°, 0.05°, 8.9 μm, and 11.9 μm, respectively. Regarding the GaN crystal substrate of Example B-5, they were 0.26°, 0.74°, 9.5 μm, and 8.9 μm, respectively. Regarding the GaN crystal substrate of Example B-6, they were 0.04°, 0.11°, 4.5 μm, and −18.6 μm, respectively. Regarding the GaN crystal substrate of Example B-7, they were 0.14°, 0.59°, −8.2 μm, and 3.4 μm, respectively. Regarding the GaN crystal substrate of Example B-8, they were 0.04°, 0.20°, 0.0 μm, and 8.9 μm, respectively. Regarding the GaN crystal substrate of Example B-9, they were 0.11°, 0.47°, −7.8 μm, and −15.2 μm, respectively. Regarding the GaN crystal substrate of Example B-10, they were 0.07°, 0.30°, −16.7 μm, and 10.3 μm, respectively. Regarding the GaN crystal substrate of Example B-11, they were 0.04°, 0.58°, −8.5 μm, and −15.2 μm, respectively. Regarding the GaN crystal substrate of Example B-12, they were 0.01°, 0.21°, −5.8 μm, and 5.6 respectively. Regarding the GaN crystal substrate of Example B-13, they were 0.03°, 0.48°, 7.8 and −16.7 μm, respectively. Regarding the GaN crystal substrate of Example B-14, they were 0.02°, 0.31°, −8.5 μm, and −12.4 μm, respectively. The results are summarized in Table 2.

2. Growth of Group III Nitride Semiconductor Layer

Then, on the front main surface of the GaN crystal substrates of the 17 different types each, a group III nitride semiconductor layer was grown in a similar manner to Example A. The surface of the semiconductor layer-stack wafer thus obtained was observed with a differential interference microscope. It was observed that the group III nitride semiconductor epitaxial layer epitaxially grown in the <10-10> direction and the <12-10> direction was recessed (depressed) in the vicinity of the c-axis-inverted crystal region. The area ratio of this depression and the distribution of the emission wavelength within the main surface of the semiconductor layer-stack wafer thus obtained were also evaluated in a similar manner to Example A.

3. Fabrication of Device

Then, in a similar manner to Example A, from each of the semiconductor layer-stack wafers of the different types as described above, 100 LD chips were obtained, namely total 1700 LD chips were obtained from the semiconductor layer-stack wafers of the 17 different types.

For the LD chips obtained from each wafer, the ratio of accepted chips was calculated in a similar manner to Example A.

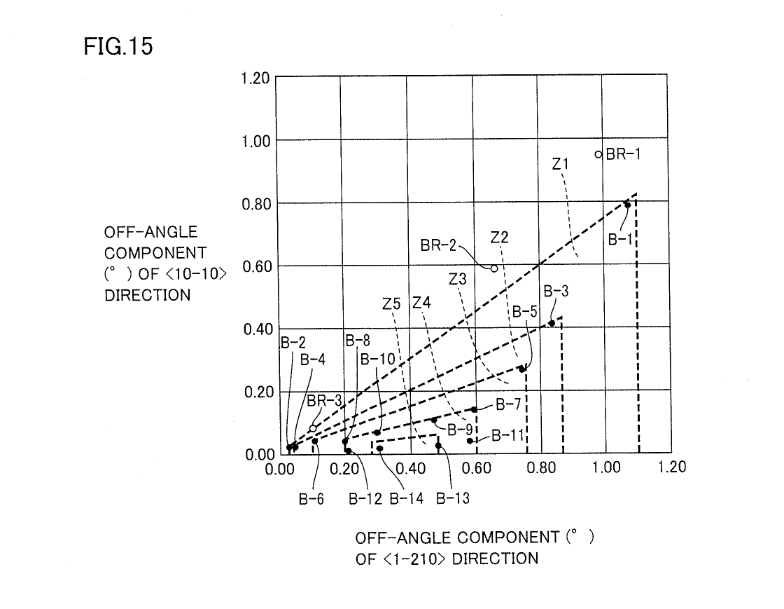

For the LD chips of the 17 different types each, the area ratio of the depression, the distribution of the emission wavelength within the main surface, and the ratio of accepted chips were as follows. Regarding the LD of Example BR-1, they were 2.04, 19 nm, and 38%, respectively. Regarding the LD of Example BR-2, they were 1.72, 21 nm, and 34%, respectively. Regarding the LD of Example BR-3, they were 1.78, 17 nm, and 48%, respectively. Regarding the LD of Example B-1, they were 0.89, 12 nm, and 74%, respectively. Regarding the LD of Example B-2, they were 0.86, 12 nm, and 73%, respectively. Regarding the LD of Example B-3, they were 0.51, 9 nm, and 81%, respectively. Regarding the LD of Example B-4, they were 0.52, 9 nm, and 80%, respectively. Regarding the LD of Example B-5, they were 0.44, 8 nm, and 83%, respectively. Regarding the LD of Example B-6, they were 0.45, 8 nm, and 83%, respectively. Regarding the LD of Example B-7, they were 0.26, 7 nm, and 90%, respectively. Regarding the LD of Example B-8, they were 0.25, 7 nm, and 91%, respectively. Regarding the LD of Example B-9, they were 0.27, 7 nm, and 90%, respectively. Regarding the LD of Example B-10, they were 0.24, 7 nm, and 89%, respectively. Regarding the LD of Example B-11, they were 0.24, 6 nm, and 92%, respectively. Regarding the LD of Example B-12, they were 0.27, 6 nm, and 91%, respectively. Regarding the LD of Example B-13, they were 0.07, 3 nm, and 97%, respectively. Regarding the LD of Example B-14, they were 0.08, 3 nm, and 94%, respectively. The results are summarized in Table 2. Further, regarding the main surface of the GaN crystal substrate of the LD in each of Examples BR-1 to BR-3 and Examples B-1 to B-14, absolute value |θ₂| of the off-angle component of the <10-10> direction defined as the second direction and absolute value |θ₁| of the off-angle component of the <1-210> direction defined as first direction are shown in the graph of FIG. 15.

TABLE 2

| | physical properties of substrate | | | | | | | | | | |
|---|---|---|---|---|---|---|---|---|---|---|---|
| | | | off angle θ | | | | | | | | |
| | | | absolute value | absolute value | | | | | | | |
| | | | \|θ₂\| of off-angle | \|θ₁\| of off-angle | warp of main | | characteristics of device | | | | |
| | | | component of | component of | surface | | | | distribution of | | |
| | c-axis-inverted | | <10-10> | <1-210> | front | rear | | | emission | | |
| | crystal region | | direction, i.e., | direction, i.e., | main | main | | area | wavelength | ratio of | (note:) |
| Example | diameter | pitch | second direction | first direction | surface | surface | | ratio of | within main | accepted | range of |
| B | (μm) | (μm) | (°) | (°) | (μm) | (μm) | type | depression | surface (nm) | chips (%) | off angle |
| Example | 60 | 1000 | 0.95 | 0.99 | 11.9 | 11.9 | LD | 2.04 | 19 | 38 | out of Z1 |
| BR-1 | | | | | | | | | | | |
| Example | 60 | 1000 | 0.59 | 0.66 | −9.6 | 4.5 | LD | 1.72 | 21 | 34 | out of Z1 |
| BR-2 | | | | | | | | | | | |
| Example | 60 | 1000 | 0.10 | 0.09 | 7.8 | 4.5 | LD | 1.78 | 17 | 48 | out of Z1 |
| BR-3 | | | | | | | | | | | |
| Example | 60 | 1000 | 0.78 | 1.08 | 8.9 | 7.8 | LD | 0.89 | 12 | 74 | Z1 |
| B-1 | | | | | | | | | | | |
| Example | 60 | 1000 | 0.02 | 0.03 | −11.6 | 17.8 | LD | 0.86 | 12 | 73 | Z1 |
| B-2 | | | | | | | | | | | |
| Example | 60 | 1000 | 0.41 | 0.84 | 4.5 | 14.7 | LD | 0.51 | 9 | 81 | Z2 |
| B-3 | | | | | | | | | | | |
| Example | 60 | 1000 | 0.02 | 0.05 | 8.9 | 11.9 | LD | 0.52 | 9 | 80 | Z2 |
| B-4 | | | | | | | | | | | |
| Example | 60 | 1000 | 0.26 | 0.74 | 9.5 | 8.9 | LD | 0.44 | 8 | 83 | Z3 |
| B-5 | | | | | | | | | | | |
| Example | 60 | 1000 | 0.04 | 0.11 | 4.5 | −18.6 | LD | 0.45 | 8 | 83 | Z3 |
| B-6 | | | | | | | | | | | |
| Example | 60 | 1000 | 0.14 | 0.59 | −8.2 | 3.4 | LD | 0.26 | 7 | 90 | Z4 |
| B-7 | | | | | | | | | | | |
| Example | 60 | 1000 | 0.04 | 0.20 | 0.0 | 8.9 | LD | 0.25 | 7 | 91 | Z4 |
| B-8 | | | | | | | | | | | |
| Example | 60 | 1000 | 0.11 | 0.47 | −7.8 | −15.2 | LD | 0.27 | 7 | 90 | Z4 |
| B-9 | | | | | | | | | | | |
| Example | 60 | 1000 | 0.07 | 0.30 | −16.7 | 10.3 | LD | 0.24 | 7 | 89 | Z4 |
| B-10 | | | | | | | | | | | |
| Example | 60 | 1000 | 0.04 | 0.58 | −8.5 | −15.2 | LD | 0.24 | 6 | 92 | Z4 |
| B-11 | | | | | | | | | | | |
| Example | 60 | 1000 | 0.01 | 0.21 | −5.8 | 5.6 | LD | 0.27 | 6 | 91 | Z4 |
| B-12 | | | | | | | | | | | |
| Example | 60 | 1000 | 0.03 | 0.48 | 7.8 | −16.7 | LD | 0.07 | 3 | 97 | Z5 |
| B-13 | | | | | | | | | | | |
| Example | 60 | 1000 | 0.02 | 0.31 | −8.5 | −12.4 | LD | 0.08 | 3 | 94 | Z5 |
| B-14 | | | | | | | | | | | |

As clearly seen from Table 2 and FIG. 15, in the case where the group III nitride semiconductor light-emitting devices functioning as LD had off angle θ between the main surface of the GaN crystal substrate and the {0001} plane that met the condition that absolute value |θ₂| of the off-angle component of the <10-10> direction defined as the second direction and absolute value |θ₁| of the off-angle component of the <1-210> direction defined as the first direction were within Range Z1 (0.03°≦|θ₁|≦1.1° and |θ₂|≦0.75×|θ₁|), the area ratio of the depression was low, the distribution of the emission wavelength within the main surface was small, and the ratio of accepted chips was high. The effect that the area ratio of the depression was decreased, the distribution of the emission wavelength within the main surface was reduced, and the ratio of accepted chips was increased was greater in the case where absolute value |θ₂| of the off-angle component of the <10-10> direction defined as the second direction and absolute value |θ₁| of the off-angle component of the <1-210> direction defined as the first direction were within Range Z2 (0.05°≦|θ₁|≦0.86° and |θ₂|≦0.5×|θ₁|), more greater in the case where they were within Range Z3 (0.11°≦|θ₁|≦0.76° and |θ₂|≦0.375×|θ₁|), still more greater in the case where they were within Range Z4 (0.2°≦|θ₁|≦0.6° and |θ₂|≦0.25×|θ₁|), and further greater in the case where they were within Range Z5 (0.3°≦|θ₁|≦0.5° and |θ₂≦0.125×|θ₁|).

### Example C

I. Preparation of GaN Crystal Substrate

GaN crystal substrates of 11 different types were prepared in a similar manner to Example A.

Regarding each of the GaN crystal substrates of the 11 different types, absolute value |θ₁| of the off-angle component of the <10-10> direction, absolute value |θ₂| of the off-angle component of the <1-210> direction, the warp of the front main surface, and the warp of the rear main surface were as follows. Regarding the GaN crystal substrate of Example CR-1, they were 1.09°, 0.93°, 8.9 μm, and 12.0 μm, respectively. Regarding the GaN crystal substrate of Example CR-2, they were 0.65°, 0.65°, −7.8 μm, and −5.7 μm, respectively. Regarding the GaN crystal substrate of Example CR-3, they were 0.10°, 0.11°, 8.9 μm, and −11.2 μm, respectively. Regarding the GaN crystal substrate of Example C-1, they were 1.06°, 0.77°, −14.3 μm, and 12.8 respectively. Regarding the GaN crystal substrate of Example C-2, they were 0.03°, 0.02°, 4.5 μm, and −11.5 μm, respectively. Regarding the GaN crystal substrate of Example C-3, they were 0.58°, 0.13°, −8.5 μm, and −15.2 μm, respectively. Regarding the GaN crystal substrate of Example C-4, they were 0.20°, 0.04°, 0.0 μm, and 5.6 μm, respectively. Regarding the GaN crystal substrate of Example C-5, they were 0.46°, 0.11°, 7.8 μm, and −11.6 μm, respectively. Regarding the GaN crystal substrate of Example C-6, they were 0.30°, 0.07°, 5.8 μm, and 11.4 μm, respectively. Regarding the GaN crystal substrate of Example C-7, they were 0.57°, 0.04°, 5.9 μm, and −8.0 μm, respectively. Regarding the GaN crystal substrate of Example C-8, they were 0.20°, 0.01°, 11.9 μm, and 4.5 μm, respectively. The results are summarized in Table 3.

2. Growth of Group III Nitride Semiconductor Layer

Then, on the front main surface of the GaN crystal substrates of the 11 different types each, MOCVD was performed to grow at least one group III nitride crystal layer. Specifically, an n-type GaN layer doped with Si and having a thickness of 5 μm; a 3-cycle MQW (multiple quantum well) structure active layer made up of an un-doped In_{0.2}Ga_{0.8}N layer having a thickness of 3 nm and an un-doped GaN layer having a thickness of 15 nm; an Al_{0.2}Ga_{0.8}N block layer doped with Mg and having a thickness of 60 nm; and a p-type GaN contact layer doped with Mg and having a thickness of 150 nm, which were included in the at least one group III nitride crystal layer, were successively grown to obtain a semiconductor layer-stack wafer. The surface of the semiconductor layer-stack wafer thus obtained was observed with a differential interference microscope. It was observed that the group III nitride semiconductor epitaxial layer grown in the <10-10> direction and the <12-10> direction was recessed (depressed) in the vicinity of the c-axis-inverted crystal region. The area ratio of this depression and the distribution of the emission wavelength within the main surface of the semiconductor layer-stack wafer thus obtained were also evaluated in a similar manner to Example A.

3. Fabrication of Device

Next, a first electrode of 80 μm in diameter×100 nm in thickness was formed at a position corresponding to the central portion of the rear surface of the GaN crystal substrate to be obtained when the above-described semiconductor layer-stack wafer was divided into chips, a second electrode of 150 μm in diameter×100 nm in thickness was formed at a position corresponding to the central portion of the main surface of the p-type GaN contact layer, and accordingly a semiconductor light-emitting device wafer was obtained. Then, each semiconductor light-emitting device wafer was divided into 100 chips each having a size of 400 μm×400 μm. Namely, from the semiconductor light-emitting device wafers of the 11 different types, total 1100 LED chips were obtained. For the 100 LED chips of each type, the emission intensity was measured. LED chips of the emission intensity larger than a predetermined standard value were accepted, and the ratio of accepted chips was calculated.

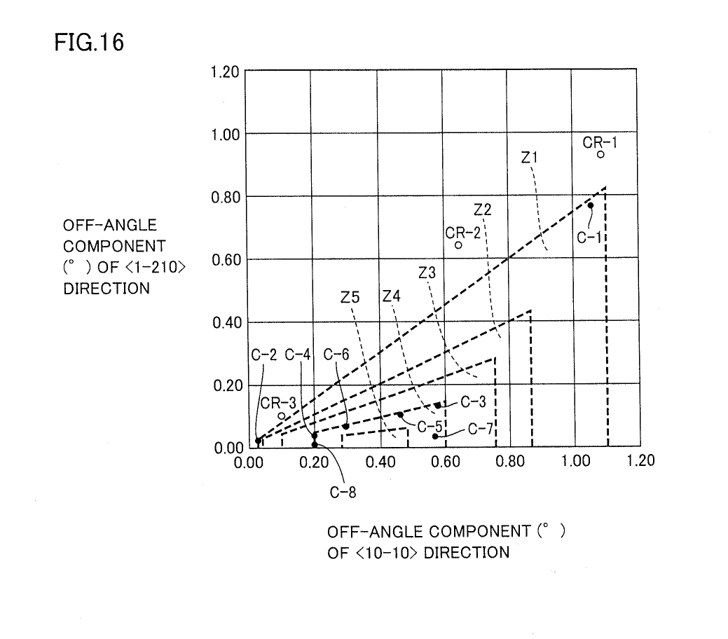

For the LEDs of the 11 different types each, the area ratio of the depression, the distribution of the emission wavelength within the main surface, and the ratio of accepted chips were as follows. Regarding the LED of Example CR-1, they were 1.97, 18 nm, and 42%, respectively. Regarding the LED of Example CR-2, they were 1.85, 19 nm, and 41%, respectively. Regarding the LED of Example CR-3, they were 1.85, 19 nm, and 39%, respectively. Regarding the LED of Example C-1, they were 0.76, nm, and 82%, respectively. Regarding the LED of Example C-2, they were 0.85, 12 nm, and 84%, respectively. Regarding the LED of Example C-3, they were 0.21, 5 nm, and 94%, respectively. Regarding the LED of Example C-4, they were 0.23, 5 nm, and 96%, respectively. Regarding the LED of Example C-5, they were 0.20, 4 nm, and 93%, respectively. Regarding the LED of Example C-6, they were 0.21, 6 nm, and 95%, respectively. Regarding the LED of Example C-7, they were 0.24, 4 nm, and 95%, respectively. Regarding the LED of Example C-8, they were 0.20, 4 nm, and 93%, respectively. The results are summarized in Table 3. Further, regarding the main surface of the GaN crystal substrate of the LED in each of Examples CR-1 to CR-3 and Examples C-1 to C-8, absolute value |θ₁| of the off-angle component of the <10-10> direction defined as the first direction and absolute value |θ₂| of the off-angle component of the <1-210> direction defined as the second direction are shown in the graph of FIG. 16.

TABLE 3

| | physical properties of substrate | | | | | | | | | | |
|---|---|---|---|---|---|---|---|---|---|---|---|
| | | | off angle θ | | | | | | | | |
| | | | absolute value | absolute value | | | | | | | |
| | | | \|θ₁\| of off-angle | \|θ₂\| of off-angle | warp of main | | characteristics of device | | | | |
| | | | component of | component of | surface | | | | distribution of | | |
| | c-axis-inverted | | <10-10> | <1-210> | front | rear | | | emission | | |
| | crystal region | | direction, i.e., | direction, i.e., | main | main | | area | wavelength | ratio of | (note:) |
| Example | diameter | pitch | first direction | second direction | surface | surface | | ratio of | within main | accepted | range of |
| C | (μm) | (μm) | (°) | (°) | (μm) | (μm) | type | depression | surface (nm) | chips (%) | off angle |
| Example | 60 | 1000 | 1.09 | 0.93 | 8.9 | 12.0 | LED | 1.97 | 18 | 42 | out of Z1 |
| CR-1 | | | | | | | | | | | |
| Example | 60 | 1000 | 0.65 | 0.65 | −7.8 | −5.7 | LED | 1.85 | 19 | 41 | out of Z1 |
| CR-2 | | | | | | | | | | | |
| Example | 60 | 1000 | 0.10 | 0.11 | 8.9 | −11.2 | LED | 1.85 | 19 | 39 | out of Z1 |
| CR-3 | | | | | | | | | | | |
| Example | 60 | 1000 | 1.06 | 0.77 | −14.3 | 12.8 | LED | 0.76 | 10 | 82 | Z1 |
| C-1 | | | | | | | | | | | |
| Example | 60 | 1000 | 0.03 | 0.02 | 4.5 | −11.5 | LED | 0.85 | 12 | 84 | Z1 |
| C-2 | | | | | | | | | | | |
| Example | 60 | 1000 | 0.58 | 0.13 | −8.5 | −15.2 | LED | 0.21 | 5 | 94 | Z4 |
| C-3 | | | | | | | | | | | |
| Example | 60 | 1000 | 0.20 | 0.04 | 0.0 | 5.6 | LED | 0.23 | 5 | 96 | Z4 |
| C-4 | | | | | | | | | | | |
| Example | 60 | 1000 | 0.46 | 0.11 | 7.8 | −11.6 | LED | 0.20 | 4 | 93 | Z4 |
| C-5 | | | | | | | | | | | |
| Example | 60 | 1000 | 0.30 | 0.07 | 5.8 | 11.4 | LED | 0.21 | 6 | 95 | Z4 |
| C-6 | | | | | | | | | | | |
| Example | 60 | 1000 | 0.57 | 0.04 | 5.9 | −8.0 | LED | 0.24 | 4 | 95 | Z4 |
| C-7 | | | | | | | | | | | |
| Example | 60 | 1000 | 0.20 | 0.01 | 11.9 | 4.5 | LED | 0.20 | 4 | 93 | Z4 |
| C-8 | | | | | | | | | | | |

As clearly seen from Table 3 and FIG. 16, in the case where the group III nitride semiconductor light-emitting devices functioning as LED had off angle θ between the main surface of the GaN crystal substrate and the {0001} plane that met the condition that absolute value |θ₁| of the off-angle component of the <10-10> direction defined as the first direction and absolute value |θ₂| of the off-angle component of the <1-210> direction defined as the second direction were within Range Z1 (0.03°≦|θ_{1|≦1.1}° and |θ₂|≦0.75×|θ₁|), the area ratio of the depression was low, the distribution of the emission wavelength within the main surface was small, and the ratio of accepted chips was high. The effect that the area ratio of the depression was decreased, the distribution of the emission wavelength within the main surface was reduced, and the ratio of accepted chips was increased was greater in the case where absolute value |θ₁| of the off-angle component of the <10-10> direction defined as the first direction and absolute value |θ₂| of the off-angle component of the <1-210> direction defined as the second direction were within Range Z2 (0.05°≦|θ₁≦0.86° and |θ₂|≦0.5×|θ₁|), more greater in the case where they were within Range Z3 (0.11°≦|θ₁|≦0.76° and |θ₂|≦0.375×|θ₁|), still more greater in the case where they were within Range Z4 (0.2°≦|θ₁|≦0.6° and |θ₂|≦0.25×|θ₁|), and further greater in the case where they were within Range Z5 (0.3°≦|θ₁|≦0.5° and |θ₂|≦0.125×|θ₁|).

### Example D

1. Preparation of GaN Crystal Substrate

GaN crystal substrates of 11 different types were prepared in a similar manner to Example B.

Regarding each of the GaN crystal substrates of the 11 different types, absolute value |θ₂| of the off-angle component of the <10-10> direction, absolute value led of the off-angle component of the <1-210> direction, the warp of the front main surface, and the warp of the rear main surface were as follows. Regarding the GaN crystal substrate of Example DR-1, they were 0.99°, 1.00°, 12.8 μm, and 12.0 μm, respectively. Regarding the GaN crystal substrate of Example DR-2, they were 0.66°, 0.70°, 4.5 and −5.7 μm, respectively. Regarding the GaN crystal substrate of Example DR-3, they were 0.10°, 0.10°, −5.7 μm, and −11.2 μm, respectively. Regarding the GaN crystal substrate of Example D-1, they were 0.76°, 1.10°, −14.3 and 12.8 μm, respectively. Regarding the GaN crystal substrate of Example D-2, they were 0.02°, 0.03°, 8.9 μm, and −11.5 μm, respectively. Regarding the GaN crystal substrate of Example D-3, they were 0.14°, 0.59°, 5.9 μm, and 5.6 μm, respectively. Regarding the GaN crystal substrate of Example D-4, they were 0.04°, 0.20°, 11.9 μm, and −11.6 μm, respectively. Regarding the GaN crystal substrate of Example D-5, they were 0.11°, 0.48°, 5.8 and 0.0 μm, respectively. Regarding the GaN crystal substrate of Example D-6, they were 0.07°, 0.31°, 5.8 and 11.4 μm, respectively. Regarding the GaN crystal substrate of Example D-7, they were 0.04°, 0.60°, 5.9 μm, and −8.0 μm, respectively. Regarding the GaN crystal substrate of Example D-8, they were 0.01°, 0.21°, 12.0 μm, and 3.2 μm, respectively. The results are summarized in Table 4.

2. Growth of Group III Nitride Semiconductor Layer

On the front main surface of the GaN crystal substrates of the 11 different types each, a group III nitride semiconductor layer was grown in a similar manner to Example C. The surface of the semiconductor layer-stack wafer thus obtained was observed with a differential interference microscope. It was observed that the group III nitride semiconductor epitaxial layer epitaxially grown in the <10-10> direction and the <12-10> direction was recessed (depressed) in the vicinity of the c-axis-inverted crystal region. The area ratio of this depression and the distribution of the emission wavelength within the main surface of the semiconductor layer-stack wafer thus obtained were also evaluated in a similar manner to Example A.

3. Fabrication of Device

Next, in a similar manner to Example C, from the semiconductor layer-stack wafers of respective types, corresponding semiconductor light-emitting device wafers were formed. From each of the different types of semiconductor light-emitting device wafers, 100 LED chips were obtained. Namely, from the semiconductor light-emitting device wafers of 11 different types, total 1100 LED chips were obtained.

For the LED chips of the different types each, the ratio of accepted chips was calculated in a similar manner to Example C.

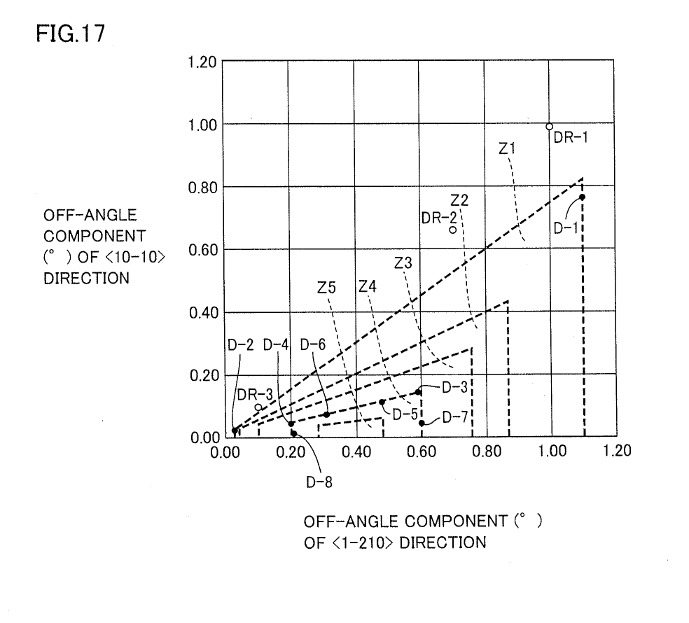

For the LEDs of the 11 different types each, the area ratio of the depression, the distribution of the emission wavelength within the main surface, and the ratio of accepted chips were as follows. Regarding the LED of Example DR-1, they were 2.04, 19 nm, and 38%, respectively. Regarding the LED of Example DR-2, they were 1.72, 21 nm, and 34%, respectively. Regarding the LED of Example DR-3, they were 1.78, 17 nm, and 48%, respectively. Regarding the LED of Example D-1, they were 0.89, 12 nm, and 74%, respectively. Regarding the LED of Example D-2, they were 0.86, 12 nm, and 73%, respectively. Regarding the LED of Example D-3, they were 0.26, 7 nm, and 90%, respectively. Regarding the LED of Example D-4, they were 0.25, 7 nm, and 91%, respectively. Regarding the LED of Example D-5, they were 0.27, 7 nm, and 90%, respectively. Regarding the LED of Example D-6, they were 0.24, 7 nm, and 89%, respectively. Regarding the LED of Example D-7, they were 0.24, 6 nm, and 92%, respectively. Regarding the LED of Example D-8, they were 0.27, 6 nm, and 91%, respectively. The results are summarized in Table 4. Further, regarding the main surface of the GaN crystal substrate of the LED in each of Examples DR-1 to DR-3 and Examples D-1 to D-8, absolute value |θ₂| of the off-angle component of the <10-10> direction defined as the second direction and absolute value |θ₁ of the off-angle component of the <1-210> direction defined as the first direction are shown in the graph of FIG. 17.

TABLE 4

| | physical properties of substrate | | | | | | | | | | |
|---|---|---|---|---|---|---|---|---|---|---|---|
| | | | off angle θ | | | | | | | | |
| | | | absolute value | absolute value | | | | | | | |
| | | | \|θ₂\| of off-angle | \|θ₁\| of off-angle | warp of main | | characteristics of device | | | | |
| | | | component of | component of | surface | | | | distribution of | | |
| | c-axis-inverted | | <10-10> | <1-210> | front | rear | | | emission | | |
| | crystal region | | direction, i.e., | direction, i.e., | main | main | | area | wavelength | ratio of | (note:) |
| Example | diameter | pitch | second direction | first direction | surface | surface | | ratio of | within main | accepted | range of |
| D | (μm) | (μm) | (°) | (°) | (μm) | (μm) | type | depression | surface (nm) | chips (%) | off angle |
| Example | 60 | 1000 | 0.99 | 1.00 | 12.8 | 12.0 | LED | 2.04 | 19 | 38 | out of Z1 |
| DR-1 | | | | | | | | | | | |
| Example | 60 | 1000 | 0.66 | 0.70 | 4.5 | −5.7 | LED | 1.72 | 21 | 34 | out of Z1 |
| DR-2 | | | | | | | | | | | |
| Example | 60 | 1000 | 0.10 | 0.10 | −5.7 | −11.2 | LED | 1.78 | 17 | 48 | out of Z1 |
| DR-3 | | | | | | | | | | | |
| Example | 60 | 1000 | 0.76 | 1.10 | −14.3 | 12.8 | LED | 0.89 | 12 | 74 | Z1 |
| D-1 | | | | | | | | | | | |
| Example | 60 | 1000 | 0.02 | 0.03 | 8.9 | −11.5 | LED | 0.86 | 12 | 73 | Z1 |
| D-2 | | | | | | | | | | | |
| Example | 60 | 1000 | 0.14 | 0.59 | 5.9 | 5.6 | LED | 0.26 | 7 | 90 | Z4 |
| D-3 | | | | | | | | | | | |
| Example | 60 | 1000 | 0.04 | 0.20 | 11.9 | −11.6 | LED | 0.25 | 7 | 91 | Z4 |
| D-4 | | | | | | | | | | | |
| Example | 60 | 1000 | 0.11 | 0.48 | 5.8 | 0.0 | LED | 0.27 | 7 | 90 | Z4 |
| D-5 | | | | | | | | | | | |
| Example | 60 | 1000 | 0.07 | 0.31 | 5.8 | 11.4 | LED | 0.24 | 7 | 89 | Z4 |
| D-6 | | | | | | | | | | | |
| Example | 60 | 1000 | 0.04 | 0.60 | 5.9 | −8.0 | LED | 0.24 | 6 | 92 | Z4 |
| D-7 | | | | | | | | | | | |
| Example | 60 | 1000 | 0.01 | 0.21 | 12.0 | 3.2 | LED | 0.27 | 6 | 91 | Z4 |
| D-8 | | | | | | | | | | | |

As clearly seen from Table 4 and FIG. 17, in the case where the group III nitride semiconductor light-emitting devices functioning as LED had off angle θ between the main surface of the GaN crystal substrate and the {0001} plane that met the condition that absolute value |θ₂| of the off-angle component of the <10-10> direction defined as the second direction and absolute value |θ₁| of the off-angle component of the <1-210> direction defined as the first direction were within Range Z1 (0.03°≦|θ₁≦1.1° and |θ₂|≦0.75×|θ₁|), the area ratio of the depression was low, the distribution of the emission wavelength within the main surface was small, and the ratio of accepted chips was high. The effect that the area ratio of the depression was decreased, the distribution of the emission wavelength within the main surface was reduced, and the ratio of accepted chips was increased was greater in the case where absolute value |θ₂| the off-angle component of the <10-10> direction defined as the second direction and absolute value |θ₁ of the off-angle component of the <1-210> direction defined as the first direction were within Range Z2 (0.05°≦|θ₁|≦0.86° and |θ₂|≦0.5×|θ₁), more greater in the case where they were within Range Z3 (0.11°≦|θ₁≦0.76° and |θ₂|≦0.375×|θ₁|), still more greater in the case where they were within Range Z4 (0.2°≦|θ₁≦0.6° and |θ₂|≦0.25×|θ₁|), and further greater in the case where they were within Range Z5 (0.3°≦|θ_{1|≦0.5}° and |θ₂≦0.125×|θ₁|).

Although the present invention has been described and illustrated in detail, it is clearly understood that the same is by way of illustration and example only and is not to be taken by way of limitation, the scope of the present invention being interpreted by the terms of the appended claims.

What is claimed is:

1. A group III nitride semiconductor light-emitting device comprising a GaN crystal substrate and at least one group III nitride semiconductor layer disposed on a main surface of said GaN crystal substrate,
said GaN crystal substrate including a matrix crystal region and a c-axis-inverted crystal region, a <1-210> direction of a crystal in said c-axis-inverted crystal region being oriented identically to a <1-210> direction of a crystal in said matrix crystal region, a <0001> direction of the crystal in said c-axis-inverted crystal region being inverted relative to a <0001> direction of the crystal in said matrix crystal region, an off angle θ being formed between said main surface and a {0001} plane, and an off-angle component of a first direction has an absolute value |θ₁| of not less than 0.03° and not more than 1.1° and an off-angle component of a second direction has an absolute value |θ₂| of not more than 0.75×|θ₁|, where the first direction is one of <10-10> and <1-210> directions and the second direction is the other of them.

2. The group III nitride semiconductor light-emitting device according to claim 1, wherein said group III nitride semiconductor layer has a laser diode structure including a first-conductivity-type layer, an active layer, and a second-conductivity-type layer.

3. The group III nitride semiconductor light-emitting device according to claim 1, wherein said group III nitride semiconductor layer has a light-emitting diode structure including a first-conductivity-type layer, an active layer, and a second-conductivity-type layer.
